(19) United States
(12) Patent Application Publication
(10) Pub. No.: US 2025/0365935 A1
(43) Pub. Date: Nov. 27, 2025

(54) MEMORY DEVICE INCLUDING LOWER ELECTRODE

(71) Applicant: SK hynix Inc., Icheon-si Gyeonggi-do (KR)

(72) Inventors: Kyung Sun RYU, Icheon-si Gyeonggi-do (KR); Beomyoung KIM, Icheon-si Gyeonggi-do (KR); Jaesuk CHOI, Icheon-si Gyeonggi-do (KR)

(73) Assignee: SK hynix Inc., Icheon-si Gyeonggi-do (KR)

(21) Appl. No.: 19/176,953

(22) Filed: Apr. 11, 2025

(30) Foreign Application Priority Data
May 21, 2024 (KR) 10-2024-0065655

(51) Int. Cl. H10B 12/00

(52) U.S. Cl. CPC H10B 12/315; H10B 12/50

(57) ABSTRACT

According to embodiments of the present disclosure, a memory device may include a substrate, a plurality of landing pads on the substrate, a plurality of lower electrodes respectively disposed on the plurality of landing pads, a first insulating layer surrounding side surfaces of the plurality of landing pads, and a second insulating layer disposed on the first insulating layer, comprising a material different from a material forming the first insulating layer, and surrounding the side surfaces of the plurality of landing pads.

### CROSS-REFERENCE TO RELATED APPLICATION

The present application claims priority under 35 U.S.C. § 119 (a) to Korean patent application number 10-2024-0065655 filed in the Korean Intellectual Property Office on May 21, 2024, which application is incorporated herein by reference in its entirety.

### TECHNICAL FIELD

Various embodiments of the present disclosure generally relate to a memory device, and more particularly, to a memory device including a lower electrode.

### BACKGROUND

A memory device is an important component in an electronics industry owing to their characteristics such as miniaturization, multi-functionality, and/or low manufacturing cost. As the electronics industry develops, memory devices are gradually becoming more highly integrated. In order to achieve high integration of the memory device, there is required to reduce a line width of a wiring included in the memory device, and there is increasing the difficulty of the process of forming the memory device.

### SUMMARY

Embodiments of the disclosure may provide a memory device including a substrate, a plurality of landing pads on the substrate, a plurality of lower electrodes respectively disposed on the plurality of landing pads, a first insulating layer surrounding side surfaces of the plurality of landing pads, and a second insulating layer disposed on the first insulating layer, comprising a material different from a material forming the first insulating layer, and surrounding the side surfaces of the plurality of landing pads.

Embodiments of the disclosure may provide a memory device including a substrate, a plurality of landing pads on the substrate, a plurality of lower electrodes respectively disposed on the plurality of landing pads, a first insulating layer surrounding side surfaces of the plurality of landing pads, a second insulating layer disposed on the first insulating layer, comprising a material different from a material forming the first insulating layer, and surrounding the side surfaces of the plurality of landing pads, and a dielectric layer disposed on surfaces of the lower electrodes and the second insulating layer, and having a lowermost surface contacting an upper surface of the second insulating layer.

Embodiments of the disclosure may provide a memory device including a substrate, a plurality of landing pads on the substrate, a plurality of lower electrodes respectively disposed on the plurality of landing pads, a dielectric layer disposed on surfaces of the plurality of lower electrodes and including a lowermost surface positioned at substantially the same level in a vertical direction as upper surfaces of the plurality of landing pads, and a plurality of support layers including a first support layer most adjacent to the substrate and a second support layer on the first support layer, a material forming the first support layer including a different material from a material forming the second support layer.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 illustrates an example of a cross-sectional structure of a memory device according to embodiments of the present disclosure.

FIG. 2 is an embodiment of an enlarged drawing of part I of FIG. 1.

FIG. 3 illustrates an example of a cross-sectional structure of a unit cell of a memory device according to embodiments of the present disclosure.

FIG. 4 illustrates an example of a planar structure of a memory device according to embodiments of the present disclosure.

FIG. 5 and FIG. 6 illustrate other examples of cross-sectional structures of a memory device according to embodiments of the present disclosure.

FIG. 7 to FIG. 12 illustrate examples of a method of forming a memory device according to embodiments of the present disclosure.

### DETAILED DESCRIPTION

Hereinafter, embodiments of the present disclosure will be described in detail with reference to accompanying drawings. In the following description of examples or embodiments of the present disclosure, reference will be made to the accompanying drawings in which it is shown by way of illustration specific examples or embodiments that can be implemented, and in which the same reference numerals and characters can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise. Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. The cross-hatching throughout the figures illustrates corresponding or similar areas between the figures rather than indicating the materials associated with the areas.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the attached drawings, the directions of an upper surface of a substrate is defined as a first direction FD and a second direction SD, respectively, and a direction protruding vertically from the upper surface of the substrate is defined as a third direction VD. The first direction FD and the second direction SD may be substantially perpendicular to each other. The third direction VD may be a direction perpendicular to the first direction FD and the second direction SD. In the following specification, ‘vertical’ or ‘vertical direction’ will be used to have substantially the same meaning as the third direction VD. The direction indicated by an arrow in the drawings and its opposite direction may indicate the same direction.

Embodiments of the disclosure may provide a memory device capable of preventing or mitigating the deterioration of device characteristics due to process defects.

The objects of the embodiments of the present disclosure are not limited to the objects described in this specification, and other objects not mentioned will be clearly understood by those skilled in the art from the description below.

According to embodiments of the present disclosure, it is possible to prevent or mitigate the deterioration of device characteristics of a memory device due to process defects.

The effects of the embodiments of the present disclosure are not limited to the effects mentioned above, and other effects not mentioned will be clearly understood by those skilled in the art from the description of the claims.

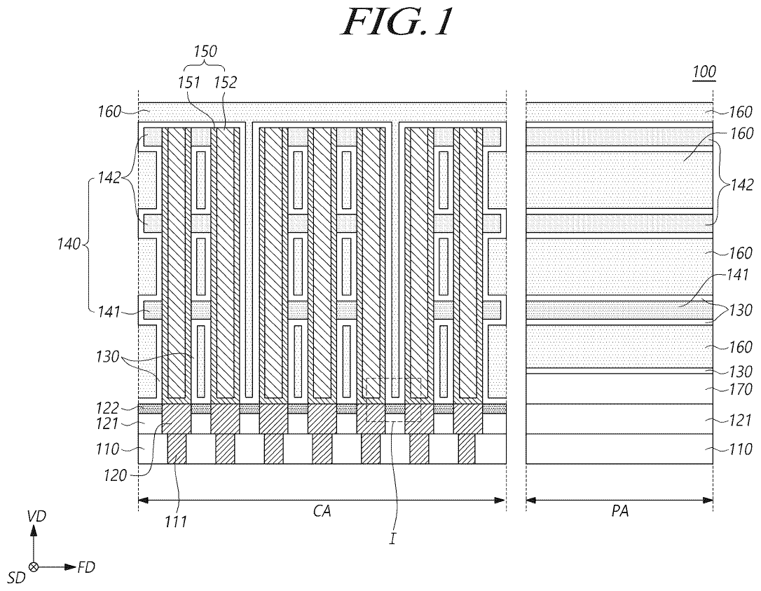

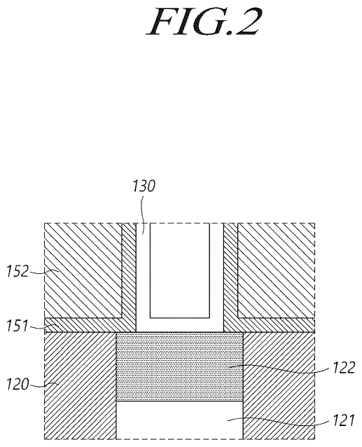

FIG. 1 illustrates an example of a cross-sectional structure of a memory device according to embodiments of the present disclosure, and FIG. 2 is an enlarged drawing of part I of FIG. 1.

Referring to FIG. 1 and FIG. 2, a memory device 100 according to an embodiment of the present disclosure may include a cell area CA and a peripheral area PA. A plurality of memory cells may be arranged in the cell area CA. The peripheral area PA may be disposed around the cell area CA. Circuits for transmitting various signals and voltages to the plurality of memory cells may be disposed in the peripheral area PA. In FIG. 1, a part of the cell area CA and a part of the peripheral area PA are illustrated for convenience of explanation.

The memory device 100 includes an isolation insulating layer 110, a plurality of contact plugs 111, a plurality of landing pads 120, a first insulating layer 121, a second insulating layer 122, a dielectric layer 130, a plurality of support layers 140, a plurality of lower electrodes 150, an upper electrode 160, and an etch stop layer 170.

In the cell area CA, the plurality of contact plugs 111 are arranged within the isolation insulating layer 110. The plurality of contact plugs 111 are arranged spaced apart from each other in the first direction FD. The isolation insulating layer 110 surrounds the side surfaces of the plurality of contact plugs 111. The upper surface of the isolation insulating layer 110 and the upper surfaces of the plurality of contact plugs 111 may form substantially the same plane.

In an embodiment, the isolation insulating layer 110 may include a nitride such as silicon nitride. In an embodiment, the plurality of contact plugs 111 may include a conductive material such as a metal, a metal oxide, a metal nitride, a metal silicide, polysilicon, a conductive carbon, or a combination thereof.

The plurality of landing pads 120 are disposed on the plurality of contact plugs 111. The plurality of landing pads 120 overlap with a plurality of contact plugs 111 in a vertical direction VD. Each of the plurality of landing pads 120 may correspond one-to-one with each of the plurality of contact plugs 111. The width of each of the plurality of landing pads 120 in the first direction FD may be greater than the width of each of the plurality of contact plugs 111 in the first direction FD. However, embodiments of the present disclosure are not limited thereto.

The first insulating layer 121 is disposed on the isolation insulating layer 110. The first insulating layer 121 overlaps with the isolation insulating layer 110 in the vertical direction VD. The first insulating layer 121 surrounds the side surfaces of the plurality of landing pads 120. The plurality of landing pads 120 are disposed between the first insulating layers 121. The upper surface of the first insulating layer 121 may be located at a lower level than the upper surfaces of the plurality of landing pads 120. In an embodiment, the first insulating layer 121 may include a nitride, such as silicon nitride.

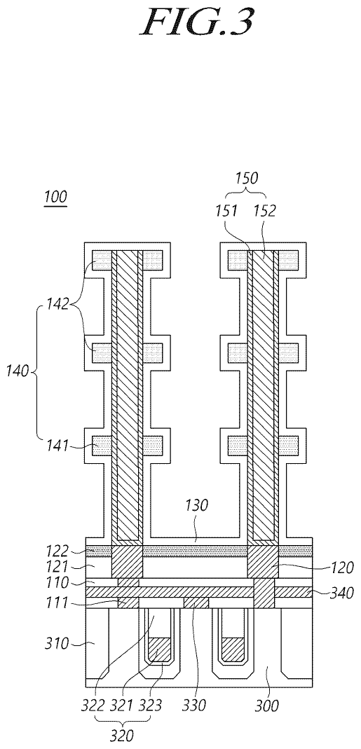

The second insulating layer 122 is disposed on the first insulating layer 121. The second insulating layer 122 overlaps the first insulating layer 121 in the vertical direction VD. The second insulating layer 122 surrounds the side surfaces of the plurality of landing pads 120. The upper surface of the second insulating layer 122 may form a substantially same plane as the upper surfaces of the plurality of landing pads 120. For example, as shown in FIG. 3, the upper surface of the second insulating layer 122 may form a substantially same plane as the upper surfaces of the plurality of landing pads 120. A thickness of the second insulating layer 122 in the vertical direction VD may be smaller than a thickness of the plurality of landing pads 120 in the vertical direction VD.

The material forming the second insulating layer 122 may include a different material from the material forming the first insulating layer 121. The second insulating layer 122 may include carbon. In an embodiment, the second insulating layer 122 may include silicon carbonitride.

The content of carbon included in the second insulating layer 122 is higher than the content of carbon included in the first insulating layer 121. For example, the first insulating layer 121 might not include carbon and the second insulating layer 122 may include carbon. Alternatively, both the first insulating layer 121 and the second insulating layer 122 may include carbon, but there may be a difference in the content of carbon.

The plurality of lower electrodes 150 are arranged on the plurality of landing pads 120. Each of the plurality of lower electrodes 150 may correspond one-to-one to each of the plurality of landing pads 120. The plurality of lower electrodes 150 overlap with the plurality of landing pads 120 in the vertical direction VD.

Each of the plurality of lower electrodes 150 may include a first lower electrode 151 and a second lower electrode 152. The lowermost surface of the first lower electrode 151 contacts with the upper surfaces of the plurality of landing pads 120. The second lower electrode 152 contacts with the first lower electrode 151. The second lower electrode 152 fills a space formed between the first lower electrodes 151. In an embodiment, because the second lower electrode 152 fills the space formed on the inner side of one of the first lower electrodes 151, there may be prevented or mitigated the leaning of the first lower electrode 151. In an embodiment, the upper surface of the second lower electrode 152 may form substantially the same plane as the upper surface of the first lower electrode 151. Alternatively, in another embodiment, the upper surface of the second lower electrode 152 may be located at a higher level in the vertical direction VD than the upper surface of the first lower electrode 151.

The first lower electrode 151 and the second lower electrode 152 may include a conductive material such as a metal, a metal oxide, a metal nitride, a metal silicide, polysilicon, conductive carbon, or a combination thereof. In an embodiment, the first lower electrode 151 may be made of a metal nitride, and the second lower electrode 152 may be made of polysilicon.

In an embodiment, the plurality of lower electrodes 150 may be in a pillar shape as described with reference to FIG. 1. In an embodiment, the plurality of lower electrodes 150 may be in a cylinder shape.

The plurality of support layers 140 are disposed between the plurality of lower electrodes 150. The plurality of support layers 140 overlap with the second insulating layer 122 in the vertical direction VD. The plurality of support layers 140 include a first support layer 141 most adjacent to the second insulating layer 122 and a second support layer 142 on the first support layer. The first support layer 141 and the second support layer 142 may be disposed to be spaced apart from each other in the vertical direction VD. The first support layer 141 may be disposed to be spaced apart from the second insulating layer 122 in the vertical direction VD.

The plurality of support layers 140 may include a nitride such as silicon nitride or silicon carbonitride. The material forming the first support layer 141 may include a different material from the material forming the second support layer 142. In an embodiment, the material forming the first support layer 141 may be silicon nitride, and the material forming the second support layer 142 may be silicon carbonitride.

The dielectric layer 130 may be disposed to cover the surfaces of the plurality of lower electrodes 150, the surfaces of the plurality of support layers 140, and the upper surface of the second insulating layer 122. The lowermost surface of the dielectric layer 130 may form substantially the same plane as the lowermost surfaces of the plurality of lower electrodes 150. For example, as shown in FIG. 3, the lowermost surface of the dielectric layer 130 may form substantially the same plane as the lowermost surfaces of the plurality of lower electrodes 150. The lowermost surface of the dielectric layer 130 may contact the upper surface of the second insulating layer 122. The dielectric layer 130 may include a high-k dielectric material, silicon oxide, silicon nitride, or a combination thereof.

The upper electrode 160 may be disposed on the surface of the dielectric layer 130. The upper electrode 160 is arranged to fill between the plurality of lower electrodes 150. The upper surface of the upper electrode 160 may be located at a higher level in the vertical direction VD than the upper surfaces of the plurality of lower electrodes 150. The upper electrode 160 may include a conductive material such as a metal, a metal oxide, a metal nitride, a metal silicide, polysilicon, conductive carbon, or a combination thereof.

The first insulating layer 121 is disposed on the isolation insulating layer 110 in the peripheral area PA. The upper surface of the first insulating layer 121 in the peripheral area PA may form substantially the same plane as the upper surface of the second insulating layer 122 in the cell area CA. A thickness of the first insulating layer 121 in the vertical direction VD in the peripheral area PA may be greater than a thickness of the first insulating layer 121 in the vertical direction VD in the cell area CA.

The etch stop layer 170 is disposed on the first insulating layer 121. In an embodiment, the etch stop layer 170 may be disposed only in the peripheral area PA and not in the cell area CA. The etch stop layer 170 may cover the entire upper surface of the first insulating layer 121 in the peripheral area PA. In an embodiment, the thickness of the etch stop layer 170 in the vertical direction VD may be 50 angstroms or more. The upper surface of the etch stop layer 170 may be located at a higher level in the vertical direction VD than the upper surface of the second insulating layer 122 in the cell area CA. The etch stop layer 170 may include a silicon nitride film or a silicon boron nitride film. The etch stop layer 170 may be a single layer or multiple layers. In an embodiment, the etch stop layer 170 may be a silicon boron nitride film.

The dielectric layer 130 may be disposed on the etch stop layer 170 in the peripheral area PA. The first support layer 141 may be disposed on the dielectric layer 130. The dielectric layer 130 is disposed on the upper and lower surfaces of the first support layer 141. The upper electrode 160 may be disposed between the dielectric layer 130 on the lower surface of the first support layer 141 and the dielectric layer 130 on the upper surface of the etch stop layer 170.

The second support layer 142 is disposed on the first support layer 141 in the peripheral area PA. The dielectric layer 130 may be disposed on the upper and lower surfaces of each of the second support layers 142. The upper electrode 160 may be disposed between the dielectric layer 130 on the upper surface of the first support layer 141 and the dielectric layer 130 on the lower surface of the second support layer 142 that is closest to the first support layer 141.

In the peripheral area PA, the upper surface of the upper electrode 160 is located at a higher level than the upper surface of the second support layer 142 which is furthest from the first support layer 141. The upper surface of the upper electrode 160 in the peripheral area PA may be located at substantially the same level as the upper surface of the upper electrode 160 in the cell area CA.

FIG. 3 illustrates an example of a cross-sectional structure of a unit cell of a memory device according to embodiments of the present disclosure.

Hereinafter, it will be omitted descriptions of components that are substantially the same as those in the previous embodiments.

Referring to FIG. 3, a memory device 100 may include a substrate 300, a device isolation layer 310, a gate structure 320, a bit line contact 330, a bit line 340, an isolation insulating layer 110, a plurality of contact plugs 111, a first insulating layer 121, a second insulating layer 122, a dielectric layer 130, a plurality of support layers 140, and a plurality of lower electrodes 150.

The substrate 300 may include a semiconductor substrate such as a silicon wafer or a Silicon-On-Insulator (SOI) wafer. The substrate 300 may include an III-V group semiconductor substrate, for example, a compound semiconductor substrate such as gallium arsenide (GaAs). The substrate 300 may include single crystal silicon, polysilicon, amorphous silicon, single crystal silicon germanium, polycrystalline silicon germanium, carbon doped silicon, or a combination thereof.

The substrate 300 includes at least one device isolation layer 310. The device isolation layer 310 may be formed using a trench device isolation technology such as shallow trench isolation (STI). The device isolation layer 310 may include silicon oxide, silicon nitride, silicon oxynitride, low-K dielectrics, high-K dielectrics, or a combination thereof.

The gate structure 320 may be embedded in the device isolation layer 310. The gate structure 320 includes a word line 321, a gate capping layer 322, and a gate dielectric layer 323. An upper surface of the word line 321 is located at a lower level than an upper surface of the device isolation layer 310. The word line 321 may be a buried gate or a buried word line. The gate capping layer 322 is disposed on the word line 321. The gate dielectric layer 323 surrounds the side surfaces of the word line 321 and the gate capping layer 322.

The word line 321 may include a conductive material such as a metal, a metal oxide, a metal nitride, a metal silicide, polysilicon, a conductive carbon, or a combination thereof. The gate capping layer 322 may include silicon oxide, silicon nitride, silicon oxynitride, a low-k dielectric, a high-k dielectric, or a combination thereof. The gate dielectric layer 323 may include silicon oxide, silicon nitride, silicon oxynitride, a high-k dielectric, or a combination thereof.

The bit line contact 330, the plurality of contact plugs 111, and the isolation insulating layer 110 are disposed on the substrate 300. The bit line contact 330 may include a conductive material such as a metal, a metal oxide, a metal nitride, a metal silicide, polysilicon, conductive carbon, or a combination thereof.

The bit line 340 may be disposed on the bit line contact 330. The bit line 340 may be disposed in a direction perpendicular to the word line 321. The bit line 340 might not be in contact with the plurality of contact plugs 111. That is, although not shown, an insulating layer may be arranged between the bit line 340 and the plurality of contact plugs 111. The bit line 340 may include a conductive material such as a metal, a metal oxide, a metal nitride, a metal silicide, polysilicon, conductive carbon, or a combination thereof.

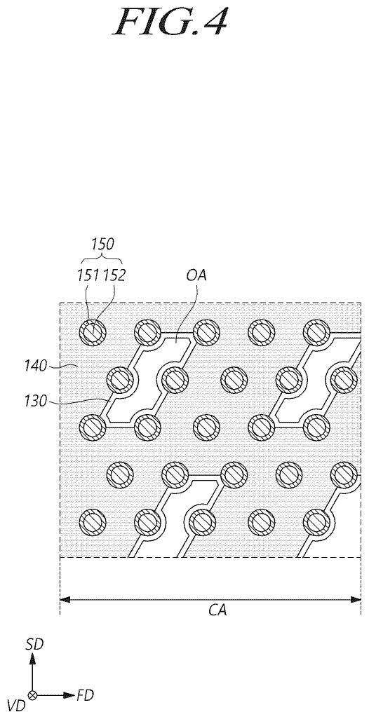

FIG. 4 illustrates an example of a planar structure of a memory device according to embodiments of the present disclosure.

Referring to FIG. 4, in the cell area CA, a plurality of lower electrodes 150 are disposed between a plurality of support layers 140. The plurality of lower electrodes 150 may be spaced apart at a constant interval. The plurality of support layers 140 surround the side surfaces of the plurality of lower electrodes 150. The dielectric layer 130 surrounds the plurality of support layers 140.

At least some of the plurality of lower electrodes 150 might not be surrounded by the plurality of support layers 140. That is, the plurality of support layers 140 may include an opening area OA. In FIG. 4, the opening area OA of the plurality of support layers 140 is illustrated as a hexagon, but is not limited thereto, and the opening area OA may be formed in various shapes.

Although not illustrated in FIG. 4, an upper electrode may be disposed on the dielectric layer 130. The upper electrode may fill the interior of the opening area OA of the plurality of support layers 140.

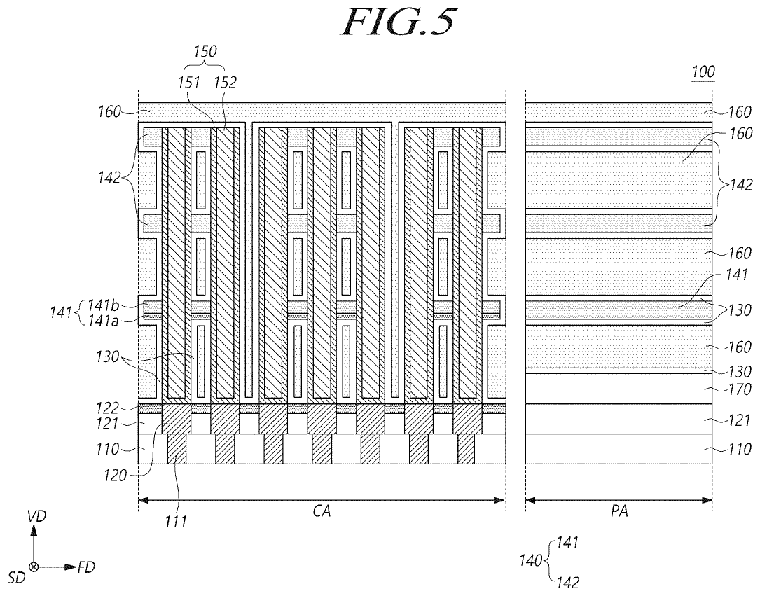

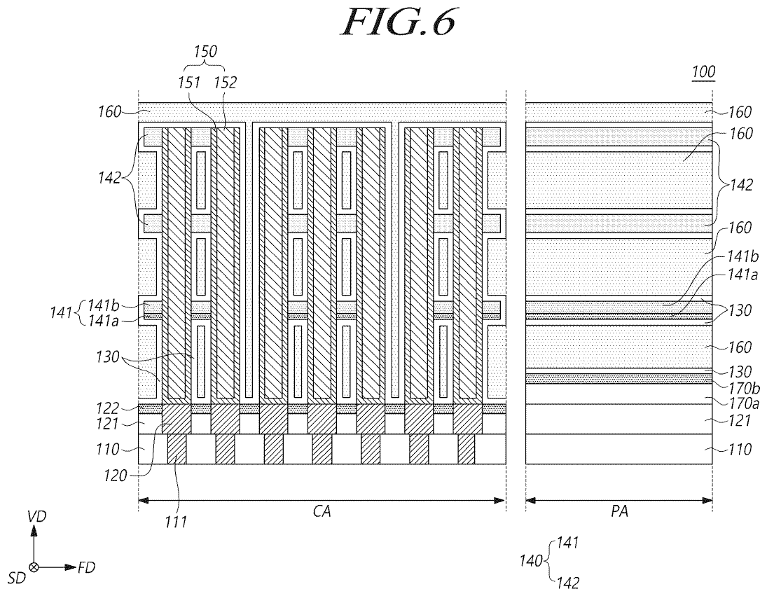

FIG. 5 and FIG. 6 illustrate other examples of cross-sectional structures of a memory device according to embodiments of the present disclosure.

In the following embodiments, it will be omitted descriptions of components that are substantially the same or similar to those in the previous embodiments.

Referring to FIG. 5, the plurality of support layers 140 include a first support layer 141 and a second support layer 142 on the first support layer 141. The first support layer 141 includes a first layer 141a and a second layer 141b on the first layer 141a. The first layer 141a is closer to the second insulating layer 122 in the vertical direction VD than the second layer 141b.

The material forming the first layer 141a may include a different material from the material forming the second layer 141b. The first layer 141a includes carbon. In an embodiment, the first layer 141a may include silicon carbonitride.

The content of carbon included in the first layer 141a is higher than the content of carbon included in the second layer 141b. For example, the second layer 141b might not include carbon and the first layer 141a may include carbon. Alternatively, both the first layer 141a and the second layer 141b may include carbon, but there may be a difference in the content of carbon.

Referring to FIG. 6, in the peripheral area PA, the etch stop layer 170 includes a first etch stop layer 170a and a second etch stop layer 170b on the first etch stop layer 170a. The first etch stop layer 170a is closer to the first insulating layer 121 in the vertical direction VD than the second etch stop layer 170b.

The material forming the second etch stop layer 170b may include a different material from the material forming the first etch stop layer 170a. The second etch stop layer 170b includes carbon. In an embodiment, the second etch stop layer 170b may include silicon carbonitride.

The content of carbon included in the second etch stop layer 170b is higher than the content of carbon included in the first etch stop layer 170a. For example, the first etch stop layer 170a might not include carbon and the second etch stop layer 170b may include carbon. Alternatively, both the first etch stop layer 170a and the second etch stop layer 170b may include carbon, but there may be a difference in the content of carbon.

In the peripheral area PA, the first support layer 141 includes a first layer 141a and a second layer 141b on the first layer 141a. In an embodiment, the first layer 141a may include silicon carbonitride.

The content of carbon included in the first layer 141a is higher than the content of carbon included in the second layer 141b. For example, the second layer 141b might not include carbon and the first layer 141a may include carbon. Alternatively, both the first layer 141a and the second layer 141b may include carbon, but there may be a difference in the content of carbon.

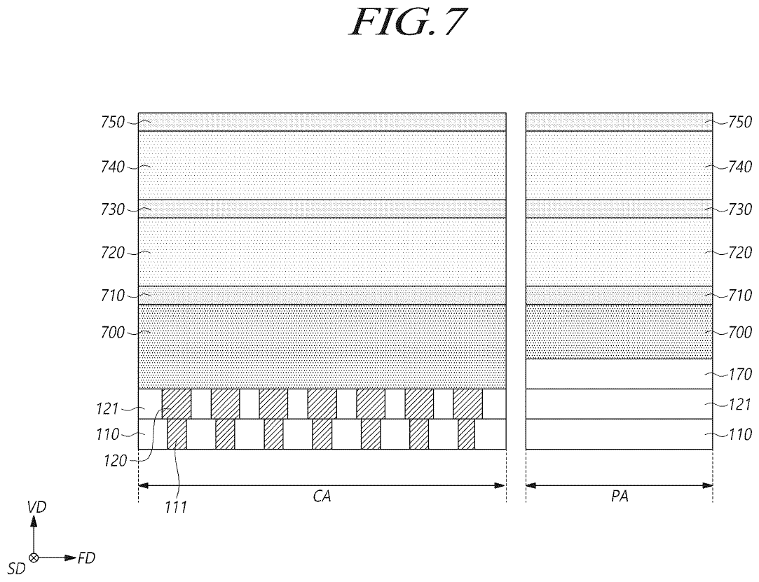

FIG. 7 to FIG. 12 illustrate examples of a method of forming a memory device according to embodiments of the present disclosure.

Referring to FIG. 7, an isolation insulating layer 110 is formed in the cell area CA and the peripheral area PA. A plurality of contact plugs 111 are formed within the isolation insulating layer 110 in the cell area CA. The plurality of contact plugs 111 are spaced apart from each other in the first direction FD.

A first insulating layer 121 is formed on the isolation insulating layer 110 and the plurality of contact plugs 111 of the cell area CA and the isolation insulating layer 110 of the peripheral area PA. A plurality of landing pads 120 are formed within the first insulating layer 121 in the cell area CA. The plurality of landing pads 120 overlap with the plurality of contact plugs 111 in the vertical direction VD. The first insulating layer 121 overlaps with the isolation insulating layer 110 in the vertical direction VD.

An etch stop layer 170 is formed on the first insulating layer 121 of the peripheral area PA. The etch stop layer 170 might not be formed in the cell area CA. In an embodiment, the thickness of the etch stop layer 170 in the vertical direction VD may be 50 angstroms or more.

A first mold layer 700 is formed on the first insulating layer 121 of the cell area CA, the plurality of landing pads 120, and the etch stop layer 170 of the peripheral area PA. The upper surface of the first mold layer 700 formed in the cell area CA may be located at the same level in the vertical direction VD as the upper surface of the first mold layer 700 formed in the peripheral area PA. The first mold layer 700 includes carbon. In an embodiment, the first mold layer 700 may be hydrocarbon.

A first material layer 710 is formed on the first mold layer 700 of the cell area CA and the peripheral area PA. The first material layer 710 may include silicon nitride and silicon carbonitride. In an embodiment, the first material layer 710 may be silicon nitride.

A second mold layer 720 is formed on the first material layer 710 of the cell area CA and the peripheral area PA. The second mold layer 720 may include silicon oxide. In an embodiment, the second mold layer 720 may be TEOS (Tetra Ethyl Ortho Silicate).

A second material layer 730 is formed on the second mold layer 720 of the cell area CA and the peripheral area PA. The second material layer 730 may include silicon nitride and silicon carbonitride. In an embodiment, the second material layer 730 may be silicon carbonitride.

A third mold layer 740 is formed on the second material layer 730 of the cell area CA and the peripheral area PA. The third mold layer 740 may include silicon nitride.

A third material layer 750 is formed on the third mold layer 740 of the cell area CA and the peripheral area PA. The third material layer 750 may include silicon nitride and silicon carbonitride. In an embodiment, the third material layer 750 may include the same material as the second material layer 730. In an embodiment, the third material layer 750 may be silicon carbonitride.

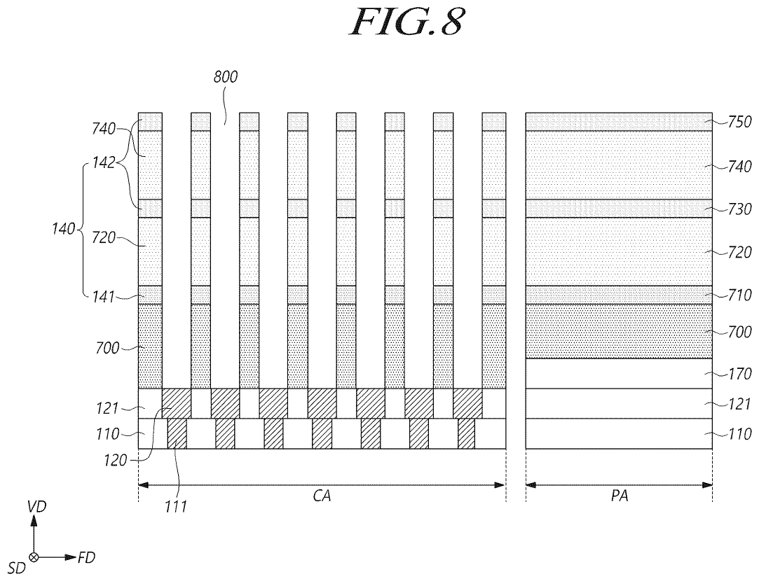

Referring to FIG. 8, a plurality of holes 800 are formed in the cell area CA through the third material layer 750, the third mold layer 740, the second material layer 730, the second mold layer 720, the first material layer 710, and the first mold layer 700. In an embodiment, the plurality of holes 800 may be formed through an anisotropic etching process. The third material layer 750, the third mold layer 740, the second material layer 730, the second mold layer 720, the first material layer 710, and the first mold layer 700 are removed by the etching process. The plurality of holes 800 overlap with the plurality of landing pads 120 in the vertical direction VD and correspond one-to-one with the plurality of landing pads 120. The plurality of holes 800 expose the upper surface of each of the plurality of landing pads 120.

In the process of forming a plurality of holes 800 in the cell area CA, the first material layer 710, the second material layer 730, and the third material layer 750 are partially removed, and the first support layer 141 and the second support layer 142 are formed.

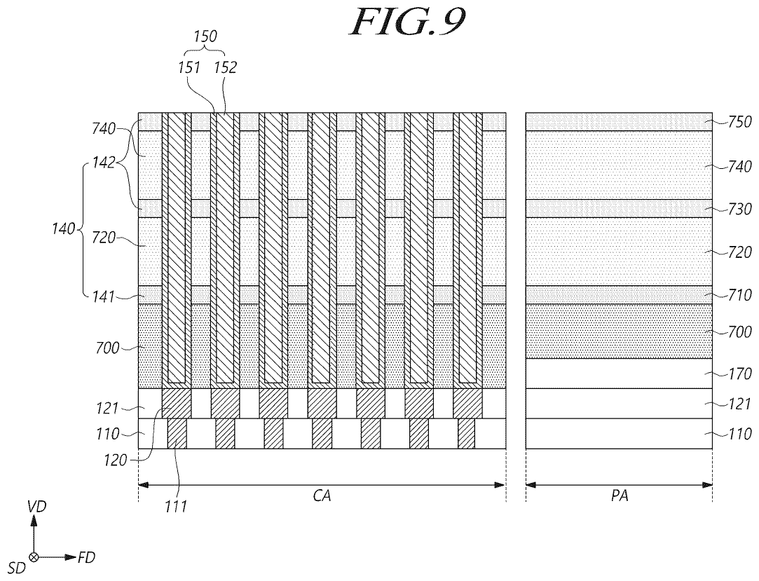

Referring to FIG. 9, a plurality of lower electrodes 150 are respectively formed inside the plurality of holes 800.

For example, a first lower electrode 151 is formed on the side walls of the plurality of holes 800 and the upper surfaces of the plurality of landing pads 120. The lowermost surface of the first lower electrode 151 may form substantially the same plane as the lowermost surface of the first mold layer 700. The outer surface of the first lower electrode 151 contacts the side surface of the first mold layer 700, the side surface of the first support layer 141, the side surface of the second mold layer 720, the side surface of the second support layer 142, and the side surface of the third mold layer 740.

The second lower electrode 152 is formed on the inner surface of the first lower electrode 151. The second lower electrode 152 fills the space formed on the inner side of the first lower electrode 151. In an embodiment, the upper surface of the first lower electrode 151 and the upper surface of the second lower electrode 152 may form substantially the same plane.

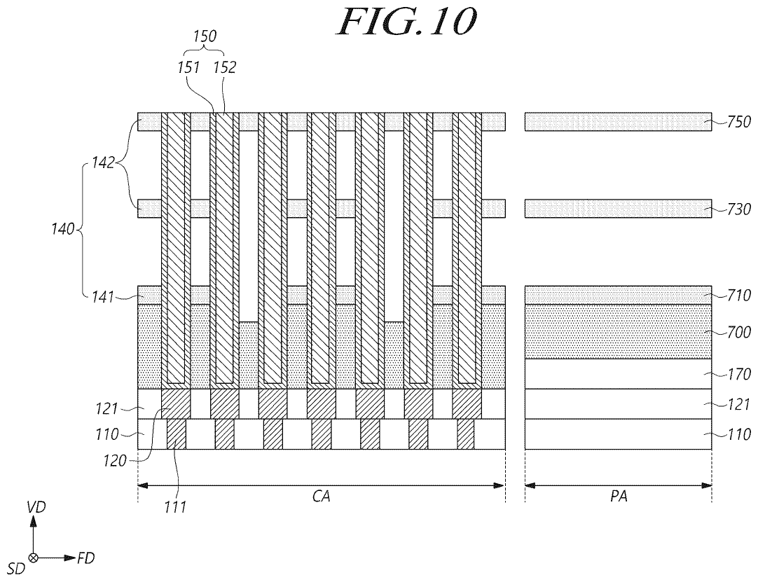

Referring to FIG. 10, in the cell area CA, a portion of the first mold layer 700, the second mold layer 720, the third mold layer 740, a portion of the first support layer 141, and a portion of the second support layer 142 are removed. The second mold layer 720 and the third mold layer 740 are removed in the peripheral area PA. In an embodiment, a portion of the first mold layer 700, the second mold layer 720, the third mold layer 740, the first support layer 141, and the second support layer 142 may be removed by a wet etching process.

In the call area CA, in an area overlapping with an area where the first support layer 141 and the second support layer 142 are removed in the vertical direction VD, the upper surface of the first mold layer 700 is located at a lower level in the vertical direction VD than the lower surface of the first support layer 141.

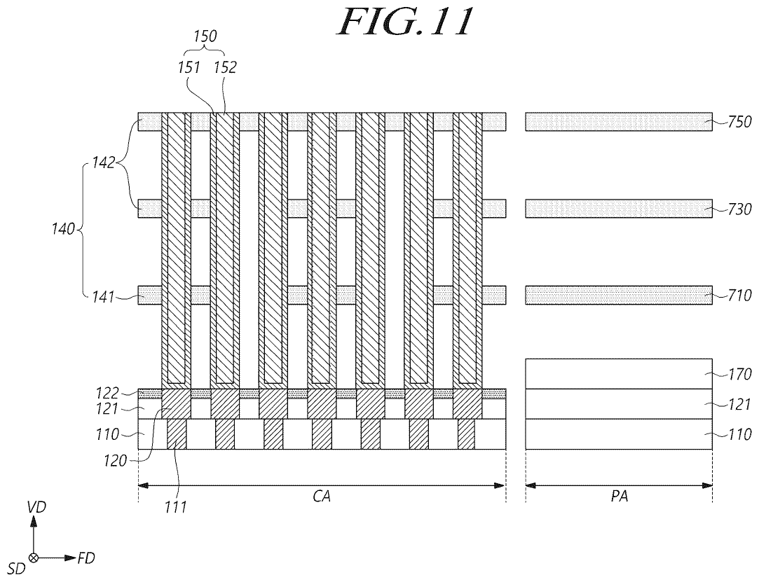

Referring to FIG. 11, the first mold layer 700 of the cell area CA and the peripheral area PA is completely removed or substantially removed. In an embodiment, the first mold layer 700 may be removed by a thermal decomposition process. In an embodiment, the thermal decomposition process may be performed at 600° C. or lower for 30 minutes or longer. In another embodiment, the first mold layer 700 may be removed by a plasma etching process. The gas used in the plasma etching process may include hydrogen (H₂) and nitrogen (N₂).

In the process of removing the first mold layer 700, carbon may be introduced into the upper surface of the first insulating layer 121 of the cell area CA. Carbon may be introduced into the first insulating layer 121 in a direction VD perpendicular to the upper surface of the first insulating layer 121.

As carbon is introduced into the first insulating layer 121, a second insulating layer 122 may be formed. The second insulating layer 122 may be a portion of the first insulating layer 121 in which the carbon content is higher than other portions of the first insulating layer 121 as carbon is introduced. In an embodiment, the carbon content in the second insulating layer 122 may be highest near the upper surface of the second insulating layer 122.

The carbon content of the second insulating layer 122 is higher than the carbon content of the first insulating layer 121. For example, the first insulating layer 121 might not include carbon, and the second insulating layer 122 may include carbon. Alternatively, both the first insulating layer 121 and the second insulating layer 122 may include carbon, but the carbon content of the first insulating layer 121 may be less than the carbon content of the second insulating layer 122. In an embodiment, the second insulating layer 122 may include a material different from the material forming the first insulating layer 121. In an embodiment, the first and second insulating layers 121 and 122 may be referred to as an insulating layer and a carbon content of the insulating layer may increase as a distance away from the substrate 300 in the vertical direction VD increases.

In an embodiment, the thickness of the second insulating layer 122 in the vertical direction VD may be smaller than the thickness of the plurality of landing pads 120 in the vertical direction VD. The upper surface of the second insulating layer 122 may form a substantially same plane as the upper surfaces of the plurality of landing pads 120. The lower surface of the second insulating layer 122 may be located at a higher level in the vertical direction VD than the lower surfaces of the plurality of landing pads 120.

In an embodiment, carbon may be introduced into the lower surface of the first support layer 141 of the cell area CA during the process of removing the first mold layer 700. The carbon may be introduced into the first support layer 141 in a direction VD perpendicular to the lower surface of the first support layer 141.

As carbon is introduced into the first support layer 141, a first layer 141a may be formed within the first support layer 141 as illustrated in FIG. 5. The first layer 141a may be a portion of the first support layer 141 in which carbon is introduced, and thus the carbon content is higher than that of other portions of the first support layer 141. In an embodiment, the carbon content within the first layer 141a may be highest near the lower surface of the first layer 141a.

In an embodiment, carbon may be introduced into the upper surface of the etch stop layer 170 of the peripheral area PA during the process of removing the first mold layer 700. The carbon may be introduced into the etch stop layer 170 in a direction VD perpendicular to the upper surface of the etch stop layer 170.

As carbon is introduced into the etch stop layer 170, a second etch stop layer 170b may be formed within the etch stop layer 170 as illustrated in FIG. 6. The second etch stop layer 170b may be a portion of the etch stop layer 170 in which the carbon content is higher than other portions of the etch stop layer 170 as carbon is introduced. In an embodiment, the carbon content within the second etch stop layer 170b may be highest near the upper surface of the second etch stop layer 170b.

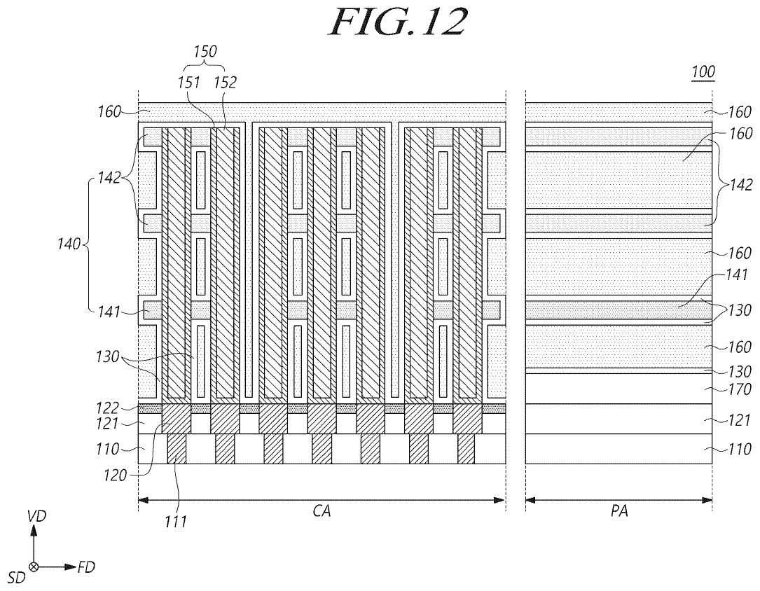

Referring to FIG. 12, a dielectric layer 130 is formed on the surface of a plurality of lower electrodes 150, the upper surface of the second insulating layer 122, and the surface of a plurality of support layers 140 in the cell area CA, and on the upper surface of the etch stop layer 170 and the surface of a plurality of support layers 140 in the peripheral area PA. The lowermost surface of the dielectric layer 130 is in contact with the upper surface of the second insulating layer 122. The lowermost surface of the dielectric layer 130 in the cell area CA is located at a lower level in the vertical direction VD than the lowermost surface of the dielectric layer 130 in the peripheral area PA.

An upper electrode 160 is formed on the surface of the dielectric layer 130. The upper electrode 160 is disposed to fill the space between the plurality of lower electrodes 150. The upper surface of the upper electrode 160 may be positioned at a higher level in the vertical direction VD than the upper surfaces of the plurality of lower electrodes 150.

The upper surface of the upper electrode 160 in the peripheral area PA may be formed at substantially the same level as the upper surface of the upper electrode 160 in the cell area CA.

Referring to FIG. 1 again, the first insulating layer 121 surrounds the side surfaces of the plurality of landing pads 120. The second insulating layer 122 is disposed on the first insulating layer 121 and surrounds the side surfaces of the plurality of landing pads 120. The upper surface of the second insulating layer 122 may form substantially the same plane as the upper surfaces of the plurality of landing pads 120. The carbon content of the second insulating layer 122 is greater than the carbon content of the first insulating layer 121.

The upper surface of the second insulating layer 122 contacts the lowermost surface of the dielectric layer 130.

The first support layer 141 may include a material different from the material forming the second support layer 142. In an embodiment, the first support layer 141 may include silicon nitride.

According to the embodiments of the present disclosure, the first mold layer 700 can be removed by a thermal decomposition process. That is, a wet etching process might not be used to remove the first mold layer 700. Because it is not required to perform the wet etching process for removing the first mold layer 700, there may be prevented or mitigated a defect caused by the etchant penetrating into the cell transistor. In addition, it is possible to prevent or mitigate the leaning of the plurality of lower electrodes 150 that may occur due to the surface tension of the etchant.

In addition, in an embodiment, because it is not required to perform the wet etching process to remove the first mold layer 700, an etch stop layer for preventing or mitigating the etchant from penetrating into the cell area CA does not need to be disposed. In an embodiment, because the etch stop layer is not disposed in the cell area CA, it is possible to reduce the number of material layers that need to be removed when forming a plurality of holes 800. Accordingly, in an embodiment, the process of forming a plurality of holes 800 can be facilitated. In addition, in an embodiment, because the etch stop layer is omitted, the dielectric layer 130 can be arranged up to the lowest surface of the plurality of lower electrodes 150, thereby further increasing the capacitance of the capacitor.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, because the embodiments disclosed in this disclosure are not intended to limit the technical idea of this disclosure but to explain the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure.

What is claimed is:

1. A memory device comprising:
a substrate extending in a first and second direction;
a plurality of landing pads on the substrate;
a plurality of lower electrodes extending in a vertical direction that intersects the first and second directions, the plurality of lower electrodes respectively disposed on the plurality of landing pads;
a first insulating layer surrounding side surfaces of the plurality of landing pads; and
a second insulating layer disposed on the first insulating layer, comprising a material different from a material forming the first insulating layer, and surrounding the side surfaces of the plurality of landing pads.

2. The memory device of claim 1, wherein the carbon content of the second insulating layer is greater than the carbon content of the first insulating layer.

3. The memory device of claim 1, wherein an upper surface of the second insulating layer forms substantially the same plane as upper surfaces of the plurality of landing pads.

4. The memory device of claim 1, wherein the second insulating layer comprises a carbon content different from a carbon content of the first insulating layer.

5. The memory device of claim 1, further comprising a dielectric layer disposed on surfaces of the lower electrodes and the second insulating layer,
wherein the lowermost surface of the dielectric layer forms substantially the same plane as the lowermost surfaces of the lower electrodes.

6. The memory device of claim 1, further comprising a plurality of support layers each respectively protruding from the lower electrodes, the support layers spaced apart from each other and located between the lower electrodes,
wherein the plurality of support layers comprise a first support layer most adjacent to the substrate and a second support layer overlapping with the first support layer in the vertical direction,
wherein a material forming the first support layer comprises a different material from a material forming the second support layer.

7. The memory device of claim 6, wherein the first support layer comprises a first layer adjacent to the substrate in the vertical direction and a second layer on the first layer,
wherein a carbon content of the first layer is higher than a carbon content of the second layer.

8. The memory device of claim 1, wherein the substrate comprises a cell area in which memory cells are disposed and a peripheral area disposed around the cell area,
wherein an upper surface of the first insulating layer disposed in the peripheral area forms substantially the same plane as an upper surface of the second insulating layer disposed in the cell area.

9. The memory device of claim 8, further comprising an etch stop layer disposed on the first insulating layer in the peripheral area.

10. The memory device of claim 9, wherein an upper surface of the etch stop layer is located at a vertically higher level than the upper surface of the second insulating layer.

11. A memory device comprising:
a substrate extending in a first and second direction;
a plurality of landing pads on the substrate;
a plurality of lower electrodes extending in a vertical direction that intersects the first and second directions, the plurality of lower electrodes respectively disposed on the plurality of landing pads;
a first insulating layer surrounding side surfaces of the plurality of landing pads;
a second insulating layer disposed on the first insulating layer, comprising a material different from a material forming the first insulating layer, and surrounding the side surfaces of the plurality of landing pads; and
a dielectric layer disposed on surfaces of the lower electrodes and the second insulating layer, and comprising a lowermost surface contacting an upper surface of the second insulating layer.

12. The memory device of claim 11, wherein the second insulating layer comprises a carbon content different from a carbon content of the first insulating layer.

13. The memory device of claim 12, wherein the carbon content of the second insulating layer is greater than the carbon content of the first insulating layer.

14. The memory device of claim 11, wherein the lowermost surface of the dielectric layer forms substantially the same plane as the lowermost surfaces of the lower electrodes.

15. The memory device of claim 11, further comprising a plurality of support layers each respectively protruding from the lower electrodes, the support layers spaced apart from each other and located between the lower electrodes,
wherein the plurality of support layers comprise a first support layer most adjacent to the substrate and a second support layer overlapping with the first support layer in the vertical direction,
wherein a material forming the first support layer comprises a different material from a material forming the second support layer.

16. The memory device of claim 11, wherein the substrate comprises a cell area in which memory cells are disposed and a peripheral area disposed around the cell area,
wherein the memory device further comprises an etch stop layer disposed on the first insulating layer in the peripheral area,
wherein the dielectric layer contacts an upper surface of the etch stop layer.

17. A memory device comprising:
a substrate extending in a first and second direction;
a plurality of landing pads on the substrate;
a plurality of lower electrodes extending in a vertical direction that intersects the first and second directions, the plurality of lower electrodes respectively disposed on the plurality of landing pads;
a dielectric layer disposed on surfaces of the plurality of lower electrodes and comprising a lowermost surface positioned at substantially the same level in the vertical direction as upper surfaces of the plurality of landing pads; and
a plurality of support layers comprising a first support layer most adjacent to the substrate and a second support layer located over the first support layer, a material forming the first support layer comprising a different material from a material forming the second support layer.

18. The memory device of claim 17, further comprising an insulating layer surrounding side surfaces of the plurality of landing pads,
wherein a carbon content of the insulating layer increases as a distance away from the substrate in the vertical direction increases.

19. The memory device of claim 18, wherein the dielectric layer contacts an upper surface of the insulating layer.

20. The memory device of claim 18, wherein the insulating layer comprises a first insulating layer and a second insulating layer on the first insulating layer,
wherein a carbon content of the second insulating layer is higher than a carbon content of the first insulating layer.
